(19) United States
(12) Patent Application Publication
(10) Pub. No.: US 2010/0148213 A1
(43) Pub. Date: Jun. 17, 2010

(54) TUNNEL DEVICE

(76) Inventors: Yen-Wei Hsu, Taipei (TW); Whel-Chyou Wu, Fremont, CA (US)

Correspondence Address: Yen-Wei Hsu, 7F No. 58, Jhouzih St.,Neihu District,, Taipei, 114, omitted

(21) Appl. No.: 12/333,318

(22) Filed: Dec. 12, 2008

(51) Int. Cl. H01L 29/88; H01L 29/93

(52) U.S. Cl. 257/105; 257/595; 257/E29.339; 257/E29.344

(57) ABSTRACT

The present invention has provided a new diode and transistor by employing the characteristic of the tunnel diode. The new diode and transistor are field interacted and can be a solarcell, light sensor, thermal device, Hall device, pressure device or acoustic device which outputs self-excited multi-band waveforms with broad bandwidth. The present invention has also revealed a precisional switch which can works at high speeds and a capacitor whose capacitance can be actively controlled.

### FIELD OF INVENTION

This invention relates to a field-interacted device, and, more particularly, to such a device can be coupled with thermal, optical, electrical, magnetic, pressure or/and acoustic fields and the device can be solarcell, light sensor, thermal device, Hall device, pressure device or acoustic device which outputs self-excited multi-band waveforms with broad bandwidth. The invention also relates to a switch which can work under high speed condictions and a capacitor whose capacitance can be actively controlled.

### BACKGROUND INFORMATION

The background includes information related to the present invention and the background information begins with the definitions of positive and negative differential resistors or respectively in short as PDR and NDR. The serially coupling of the PDR and NDR functioning as damper will also be discussed in the background information section.

### INTRODUCTION

Referring to [5], [34], [41, Vol. 1 Chapter 50] and [24, Page 402], the nonlinear system response produces many un-modeled effects: jump or singularity, bifurcation, rectification, harmonic and subharmonic generations, frequency-amplitude relationship, phase-amplitude relationship, frequency entrainment, nonlinear oscillation, stability, modulations(amplitude, frequency, phase) and chaoes. In the nonlinear analysis fields, it needs to develop the mathematical tools for obtaining the resolution of nonlinearity. Up to now, there exists three fundamental problems which are self-adjoint operator, spectral(harmonic) analysis, and scattering problems, referred to [32, Chapter 4.], [38, Page 303], [35, Chapter X], [37, Chapter XI], [36, Chapter XIII], [25] and [34, Chapter 7.].

There are many articles involved the topics of the nonlinear spectral analysis and reviewed as the following sections. The first one is the nonlinear dynamics and self-excited or self-oscillation systems. It provides a profound viewpoint of the non-linear

TABLE 1
Mechanical v.s. Electrical Systems

| Mechanical Systems | | Electrical Systems | |
|---|---|---|---|
| m | mass | L | inductance |
| y | displacement | q | charge |
| $\frac{dy}{dt} = v$ | velocity | $\frac{dq}{dt} = i$ | current |
| c | damping | R | resistance |
| k | spring constant | 1/C | reciprocal of capacitance |
| f (t) | input or driving force | E (t) | input or electromotive force |

dynamical system behaviors, which are duality of second-order systems, self-excitation, orbital equivalence or structural stability, bifurcation, perturbation, harmonic balance, transient behaviors, frequency-amplitude and phase-amplitude relation-ships, jump phenomenon or singularity occurrence, frequency entrainment or synchronization, and so on. In particular, the self-induced current (voltage) or electricity generation appears if applying to the Liénard system.

Comparision Between Electrical and Mechanical Systems

Referred to [3, Page 341], the comparison between mechanical and electrical systems as the table (1):

the damping coefficient c in a mechanical system is analogous to R in an electrical system such that the resistance R, in common, could be as a energy dissipative device. There exists a series problem caused by the analogy between the mechanical and electrical systems. As a result, the damping term has to be a specific bandwidth of frequency response and just behaved an absorbent property as the previous definitions. The resistance has neither to be the frequency response nor absorbing but just had the balance or circle feature only. This is a crucial misunderstanding for two analogous systems.

Dielectric Materials

Referring to [31, Chapter 4, 5, 8, 9], [20, Part One], [21, Chapter 1], [8, Chapter 14], the response of a material to an electric field can be used to advantage even when no charge is transferred. These effects are described by the dielectric properties of the material. Dielectric materials posses a large energy gap between the valence and conduction bands; thus the materials a high electrical resistivity. Because dielectric materials are used in the AC circuits, the dipoles must be able to switch directions, often in the high frequencies, where the dipoles are atoms or groups of atoms that have an unbalanced charge. Alignment of dipoles causes polarization which determines the behavior of the dielectric material. Electronic and ionic polarization occur easily even at the high frequencies.

Some energy is lost as heat when a dielectric material polarized in the AC electric field. The fraction of the energy lost during each reversal is the dielectric loss. The energy losses are due to current leakage and dipoles friction (or change the direction). Losses due to the current leakage are low if the electrical resistivity is high, typically which behaves 10¹¹ Ohm·m or more. Dipole friction occurs when reorientation of the dipoles is difficult, as in complex organic molecules. The greatest loss occurs at frequencies where the dipoles almost, but not quite, can be reoriented. At lower frequencies, losses are low because the dipoles have time to move. At higher frequencies, losses are low because the dipoles do not move at all.

Cauchy-Riemann Theorem

Referring to the [42], [12], [40] and [4], the complex variable analysis is a fundamental mathematical tool for the electrical circuit theory. In general, the impedance function consists of the real and imaginary parts. For each part of impedance functions, they are satisfied the Cauchy-Riemann Theorem. Let a complex function be

z(x,y)=F(x,y)+iG(x,y) (1)

where F(x, y) and G(x, y) are analytic functions in a domain D and the Cauchy-Riemann theorem is the first-order derivative of functions F(x, y) and G(x, y) with respect to x and y becomes

$$\begin{matrix}\frac{\partial F}{\partial x} = \frac{\partial G}{\partial y} \\ and & ( 2 ) \\ \frac{\partial F}{\partial y} = - \frac{\partial G}{\partial x} & ( 3 )\end{matrix}$$

Furthermore, taking the second-order derivative with respect to x and y,

$$\begin{matrix}\frac{\partial {}^{2} F}{\partial {x}^{2}} + \frac{\partial {}^{2} F}{\partial {y}^{2}} = 0 \\ and & ( 4 ) \\ \frac{\partial {}^{2} G}{\partial {x}^{2}} + \frac{\partial {}^{2} G}{\partial {y}^{2}} = 0 & ( 5 )\end{matrix}$$

also F(x, y) and G(x, y) are called the harmonic functions.

From the equation (1), the total derivative of the complex function z(x, y) is

$$d z ( x , y ) = ( \frac{\partial F}{\partial x} d x + \frac{\partial F}{\partial y} d y ) + i ( \frac{\partial G}{\partial x} d x + \frac{\partial G}{\partial y} d y ) \qquad ( 6 )$$

and substituting equations (2) and (3) into the form of (6), then the total derivative of the complex function (1) is dependent on the real function F(x, y) or in terms of the real-valued function F(x, y) (real part) only,

$$d z ( x , y ) = ( \frac{\partial F}{\partial x} d x + \frac{\partial F}{\partial y} d y ) + i ( \frac{\partial F}{\partial x} d y - \frac{\partial F}{\partial y} d x ) \qquad ( 7 )$$

and in terms of a real-valued function G(x, y) (imaginary part) only,

$$d z ( x , y ) = ( \frac{\partial G}{\partial y} d x - \frac{\partial G}{\partial x} d y ) + i ( \frac{\partial G}{\partial x} d x + \frac{\partial G}{\partial y} d y ) \qquad ( 8 )$$

There are the more crucial facts behind the (7) and (8) potentially. As a result, the total derivative of the complex function (6) depends on the real (imaginary) part of (1) function F(x, y) or G(x, y) only and never be a constant value function. One said, if changing the function of real part, the imaginary part function is also varied and determined by the real part via the equations (2) and (3). Since the functions F(x, y) and G(x, y) have to satisfy the equations (4) and (5), they are harmonic functions and then produce the frequency related elements discussed at the analytic continuation section. Moreover, the functions of real and imaginary parts are not entirely independent referred to the Hilbert transforms in the textbooks [18, Page 296] and [20, Page 5 and Appendix One].

Analytic Continuation

For each analytic function F(z) in the domain D, the Laurent series expansion of F(z) is defined as the following

$$\begin{matrix}F ( z ) = {\sum }_{n = - ∞}^{∞} {{a}_{n} ( z - {z}_{0} )}^{n} \\ = … + {{a}_{- 2} ( z - {z}_{0} )}^{- 2} {{a}_{- 1} ( z - {z}_{0} )}^{- 1} + {a}_{0} + …\end{matrix} \qquad ( 9 )$$

where the expansion center z₀ is an arbitrarily selected. Since this domain D for this analytic function F(z), any regular point imparts a center of a Laurent series [42, Page 223], i.e.,

$$F ( z ) = {\sum }_{- ∞}^{∞} {{c}_{n} ( z - {z}_{j} )}^{n}$$

where zⱼ is an arbitrary regular point in this complex analytic domain D for j=0, 1, 2, 3 . . . . For each index j, the complex variable is the product of its norm and phase,

$$z - {z}_{j} = \vert z - {z}_{j} \vert {e}^{{iθ}_{j}} and F ( z ) = {{\sum }_{- ∞}}^{∞} {c}_{n} \vert z - {z}_{j} \vert {e}^{i n {ω}_{j} t} \qquad ( 10 )$$

For each phase angle θⱼ, the corresponding frequency elements are naturally produced, say harmonic frequency ωⱼ. Now we have the following results:
1. As the current passing through any smoothing conductor (without singularities), the frequencies are induced in nature.
2. This conductor imparts an order-∞ resonant coupler.
3. This conductor is to be as an antenna without any bandwidth limitation.
4. Dynamic impedance matched.

Positive and Negative Differential Resistors (PDR, NDR)

More inventively, due to observing the positive and negative differential resistors properties qualitatively, we introduce the Cauchy-Riemann equations, [27, Part 1,2], [42], [12], [40] and [4], for describing a system impedance transient behaviors and particularly in some sophisticated characteristics system parametrization by one dedicated parameter ω. Consider the impedance z in specific variables (i, v) complex form of

z=F(i,v)+jG(i,v) (11)

where i, v are current and voltage respectively. Assumed that the functions F(i, v) and G(i, v) are analytic in the specific domain. From the Cauchy-Riemann equations (2) and (3) becomes as following

$$\begin{matrix}\frac{\partial F}{\partial i} = \frac{\partial G}{\partial v} and & ( 12 ) \\ \frac{\partial F}{\partial v} = \frac{\partial G}{\partial i} & ( 13 )\end{matrix}$$

where in these two functions there exists one relationship based on the Hilbert transforms [18, Page 296] and [20, Page 5]. In other words, the functions F(i, v) and G(i, v) do not be obtained individually. Using the chain rule, equations (12) and (13) are further obtained

$$\begin{matrix}\frac{\partial F}{\partial ω} \frac{d ω}{d i} = \frac{\partial G}{\partial ω} \frac{d ω}{d v} and & ( 14 ) \\ \frac{\partial F}{\partial ω} \frac{d ω}{d v} = - \frac{\partial G}{\partial ω} \frac{d ω}{d i} & ( 15 )\end{matrix}$$

where the parameter w could be the temperature field T, magnetic field flux intensity B, optical field intensity I, in the electric field for examples, voltage v, current i, frequency f or electrical power P, in the mechanical field for instance, magnitude of force F, and so on. Let the terms

$$\begin{matrix}\{ \begin{matrix}\frac{d ω}{d v} > 0 \\ \frac{d ω}{d i} > 0\end{matrix} or & ( 16 ) \\ \{ \begin{matrix}\frac{d ω}{d v} < 0 \\ \frac{d ω}{d i} < 0\end{matrix} & ( 17 )\end{matrix}$$

be non-zero and the same sign. Under the same sign conditions as equation (16) or (17), from equation (14) to equation (15),

$$\begin{matrix}\frac{\partial F}{\partial ω} > 0 and & ( 18 ) \\ \frac{\partial F}{\partial ω} < 0 & ( 19 )\end{matrix}$$

should be held simultaneously. From the viewpoint of making a power source, the simple way to perform equations (16) and (17) is using the pulse-width modulation (PWM) method. The further meaning of equations (16) and (17) is that using the variable frequency w in pulse-width modulation to current and voltage is the most straightforward way, i.e.,

$$\{ \begin{matrix}\frac{d ω}{d v} \neq 0 \\ \frac{d ω}{d i} \neq 0\end{matrix}$$

After obtaining the qualitative behavoirs of equation (18) and equation (19), also we need to further respectively define the quantative behavoirs of equation (18) and equation (19). Intuitively, any complete system with the system impedance equation (11) could be analogy to the simple-parallel oscillator as the FIG. 1 or series oscillator FIG. 2 which correspondent 2^{nd}—order differential equation is as (22) or (25) respectively. Referring to [41, Vol 2, Chapter 8,9,10,11,22,23], [17, Page 173], [6, Page 181], [22, Chapter 10] and [14, Page 951-968], as the FIG. 1, let the current iₗ and voltage v_{C} be replaced by x, y respectively. From the Kirchhoff's Law, this simple oscillator is expressed as the form of

$$\begin{matrix}L \frac{d x}{d t} = y & ( 20 ) \\ C \frac{d y}{d t} = - x + {F}_{p} ( y ) & ( 21 )\end{matrix}$$

or in matrix form

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}0 \\ \frac{{F}_{p} ( y )}{C}\end{matrix} ] \qquad ( 22 )$$

where the function Fₚ(y) represents the generalized Ohm's law and for the single variable case, Fₚ(x) is the real part function of the impedance function equation (11), the “p” in short, is a “parallel” oscillator. Furthermore, equation (22) is a Liénard system. If taking the linear from of Fₚ(y),

Fₚ(y)=Ky

and K>0, it is a normally linear Ohm's law. Also, the states equation of a simple series oscillator in the FIG. 2 is

$$\begin{matrix}L \frac{d x}{d t} = y - {F}_{s} ( x ) & ( 23 ) \\ C \frac{d y}{d t} = - x & ( 24 )\end{matrix}$$

in the matrix form,

$$[ \begin{matrix}\frac{d x}{d t} \\ \frac{d y}{d t}\end{matrix} ] = [ \begin{matrix}0 & \frac{1}{L} \\ - \frac{1}{C} & 0\end{matrix} ] [ \begin{matrix}x \\ y\end{matrix} ] + [ \begin{matrix}- \frac{{F}_{s} ( x )}{L} \\ 0\end{matrix} ] \qquad ( 25 )$$

The i_{C}, vₗ have to be replaced by x, y respectively. The function Fₛ(x) indicates the generalized Ohm's law and (25) is the Liénard system too. Again, considering one system as the figure (25), let L,C be to one, then the system (25) becomes the form of

$$[ \begin{matrix}\frac{d x}{d t} \\ \frac{d y}{d t}\end{matrix} ] = [ \begin{matrix}y - {F}_{s} ( x ) \\ - x\end{matrix} ] \qquad ( 26 )$$

To obtain the equilibrium point of the system (25), setting the right hand side of the system (26) is zero

$$\{ \begin{matrix}y - {F}_{s} ( 0 ) = 0 \\ - x = 0\end{matrix}$$

where Fₛ(0) is a value of the generalized Ohm's law at zero. The gradient of (26) is

$$[ \begin{matrix}- {F}_{s}^{′} ( 0 ) & 1 \\ - 1 & 0\end{matrix} ]$$

Let the slope of the generalized Ohm's law Fₛ′(0) be a new function as fₛ(0)

fₛ(0)≡Fₛ′(0)

the correspondent eigenvalues λ_{1,2}^{s} are as

$${λ}_{1 , 2}^{s} = \frac{1}{2} [ - {f}_{s} ( 0 ) \pm \sqrt{{( {f}_{s} ( 0 ) )}^{2} - 4} ]$$

Similarly, in the simple parallel oscillator (22),

fₚ(0)≡Fₚ′(0)

the equilibrium point of (22) is set to (Fₚ(0), 0) and the gradient of (22) is

$$[ \begin{matrix}0 & 1 \\ - 1 & {f}_{p} ( 0 )\end{matrix} ]$$

the correspondent eigenvalues λ_{1,2}^{p} are

$${λ}_{1 , 2}^{p} = \frac{1}{2} ( {f}_{p} \pm \sqrt{{( {f}_{p} ( 0 ) )}^{2} - 4} )$$

The qualitative properties of the systems (22) and (25), referred to [14] and [22], are as the following:
1. fₛ(0)>0, or fₚ(0)<0, its correspondent equilibrium point is a sink.
2. fₛ(0)<0, or fₚ(0)>0, its correspondent equilibrium point is a source.

Thus, observing previous sink and source quite different definitions, if the slope value of impedance function Fₛ(x) or Fₚ(y), fₛ(x) or fₚ(y) is a positive value

Fₛ′(x)=fₛ(x)>0 (27)

or

Fₚ′(y)=fₚ(y)>0 (28)

it is the name of the positive differential resistivity or PDR. On contrary, it is a negative differential resistivity or NDR.

Fₛ′(x)=fₛ(x)<0 (29)

or

Fₚ′(y)=fₚ(y)<0 (30)
3. if fₛ(0)=0 or fₚ(0)=0 its correspondent equilibrium point is a bifurcation point, referred to [23, Page 433], [24, Page 26] and [22, Chapter 10] or fixed point, [2, Chapter 1, 3, 5, 6], or singularity point, [7], [1, Chapter 22, 23, 24].

Fₛ′(x)=fₛ(x)=0 (31)

or

Fₚ′(y)=fₚ(y)=0 (32)

Liénard Stabilized Systems

Taking the system equation (22) or equation (25) is treated as a nonlinear dynamical system analysis, we can extend these systems to be a classical result on the uniqueness of the limit cycle, referred to [1, Chapter 22, 23, 24], [24, Page 402-407], [33, Page 253-260], [22, Chapter 10,11] and many articles [26], [19], [30], [28], [29], [16], [11], [39], [10], [15], [9], [13] for a dynamical system as the form of

$$\{ \begin{matrix}\frac{d x}{d t} = y - F ( x ) \\ \frac{d y}{d t} = - g ( x )\end{matrix} \qquad ( 33 )$$

under certain conditions on the functions F and g or its equivalent form of a nonlinear dynamics

$$\frac{{d}^{2} x}{d {t}^{2}} + f ( x ) \frac{d x}{d t} + g ( x ) = 0 \qquad ( 34 )$$

where the damping function f(x) is the first derivative of impedance function F(x) with respect to the state x

f(x)=F′(x) (35)

Based on the spectral decomposition theorem [23, Chapter 7], the damping function has to be a non-zero value if it is a stable system. The impedance function is a somehow specific pattern like as the FIG. 3,

y=F(x) (36)

From equation (33), equation (34) and equation (35), the impedance function F(x) is the integral of damping function f(x) over one specific operated domain x>0 as

$$F ( x ) = {\int }_{0}^{x} f ( s ) d s \qquad ( 37 )$$

Under the assumptions that F, g ∈ C¹(R), F and g are odd functions of x, F(0)=0, F′(0)<0, F has single positive zero at x=a, and F increases monotonically to infinity for x≧a as x→∞ it follows that the Liénard's system equation (33) has exactly one limit cycle and it is stable. Comparing the (37) to the bifurcation point defined in the section ( ), the initial condition of the (37) is extended to an arbitrary setting as

$$F ( x ) = {\int }_{a}^{x} f ( ζ ) d ζ \qquad ( 38 )$$

where a ∈ R. Also, the FIG. 4 is modified as where the dashed lines are different initial conditions. Based on above proof and carefully observing the function (35) in the FIG. 4, we conclude the critical insights of the system (33). We conclude that an adaptive-dynamic damping function F(x) with the following properties:
1. The damping function is not a constant. At the interval,

α≦a

the impedance function F(x) is

F(x)<0

The function derivative of F(x) should be

F′(x)=f(x)≧0 (39)

one part is a PDR as defined (27) or (28) and

F′(x)=f(x)<0 (40)

another is a NDR as defined (29) or (30), hold simultaneously. Which means that the impedance function F(x) has the negative and positive slopes at the interval α≦a.
2. Following the Liénard theorem [33, Page 253-260], [22, Chapter 10,11], [24, Chapter 8] and the correspondent theorems, corollaries and lemma, we can further conclude that one stabilized system which has at least one limit cycle, all solutions of the system (33) converge to this limit cycle even asymptotically stable periodic closed orbit. In fact, this kind of system construction can be realized a stabilized system in Poincaré sense [33, Page 253-260], [22, Chapter 10,11], [17, Chapter 1,2,3,4], [6, Chapter 3].

Furthermore, one nonlinear dynamic system is as the follow

$$\begin{matrix}\frac{{d}^{2} x}{d {t}^{2}} + ɛ f ( x , y ) \frac{d x}{d t} + g ( x ) = 0 & ( 41 ) \\ or & \\ \{ \begin{matrix}\frac{d x}{d t} = y - ɛ F ( x , y ) \\ \frac{d y}{d t} = - g ( x )\end{matrix} & ( 42 ) \\ where & \\ f ( x , y ) & ( 43 )\end{matrix}$$

is a nonzero and nonlinear damping function,

g(x) (44)

is a nonlinear spring function, and

F(x, y) (45)

is a nonlinear impedance function also they are differentiable. If the following conditions are valid
1. there exists a>0 such that f(x, y)>0 when \sqrt{x²+y²}≦a.
2. f (0, 0)<0 (hence f(x, y)<0 in a neighborhood of the origin).
3. g(0)=0, g(x)>0 when x>0, and g(x)<0 when x<0.
4.

$$G ( x ) = {\int }_{0}^{x} g ( u ) d u \to ∞ as x \to ∞ .$$

then (41) or (42) has at least one periodic solution.

Frequency-Shift Damping Effect

Referring to the books [4, p 313], [35, Page 10-11], [25, Page 13] and [40, page 171-174], we assume that the function is a trigonometric Fouries series generated by a function g(t) ∈ L(I), where g(t) should be bounded and the unbounded case in the book [40, page 171-174] has proved, and L(I) denotes Lebesgue-integrable on the interval I, then for each real β, we have

$${lim}_{ω \to ∞} {\int }_{I}^{ } g ( t ) {e}^{i ( ω t + β )} d t = 0 \qquad ( 46 )$$

where

e^{i(ωt+β)}=cos(ωt+β)+i sin(ωt+β)

the imaginary part of (46)

$${lim}_{ω \to ∞} {\int }_{I}^{ } g ( t ) sin ( ω t + β ) d t = 0 \qquad ( 47 )$$

and real part of (46)

$${lim}_{ω \to ∞} {\int }_{I}^{ } g ( t ) cos ( ω t + β ) d t = 0 \qquad ( 48 )$$

are approached to zero as taking the limit operation to infinity, ω→∞, where equation (47) or (48) is called “Riemann-Lebesgue lemma” and the parameter ω is a positive real number. If g(t) is a bounded constant and ω>0. it is naturally the (47) can be further derived into

$$\vert {\int }_{a}^{b} {e}^{i ( ω t + β )} d t \vert = \vert \frac{{e}^{i a ω} - {e}^{i b ω}}{ω} \vert \leq \frac{2}{ω}$$

where [a,b] ∈ I is the boundary condition and the result also holds if on the open interval (a, b). For an arbitrary positive real number ε>0, there exists a unit step function s(t), referred to [4, p 264], such that

$${\int }_{I}^{ } \vert g ( t ) - s ( t ) \vert d t < \frac{ɛ}{2}$$

Now there is a positive real number M such that if ω≧M,

$$\vert {\int }_{I}^{ } s ( t ) {e}^{i ( ω t + β )} d t \vert < \frac{ɛ}{2} \qquad ( 49 )$$

holds. Therefore, we have

$$\begin{matrix}\vert {\int }_{I}^{ } g ( t ) {e}^{i ( ω t + β )} d t \vert \leq \vert {\int }_{I}^{ } ( g ( t ) - s ( t ) ) {e}^{i ( ω t + β )} d t \vert + \vert {\int }_{I}^{ } s ( t ) {e}^{i ( ω t + β )} d t \vert \\ \leq {\int }_{I}^{ } \vert g ( t ) - s ( t ) \vert d t + \frac{ɛ}{2} \\ < \frac{ɛ}{2} + \frac{ɛ}{2} = ɛ\end{matrix} \qquad ( 50 )$$

i.e., (47) or (48) is verified and hold.

According to the Riemann-Lebesgue lemma, the equation (46) or (48) and (47), as the frequency ω approaches to ∞ which means

$$ω ≫ 0 \\ then \\ {lim}_{ω \to ∞} {\int }_{I} g ( t ) {e}^{i ( ω t + β )} d t = 0 \qquad ( 51 )$$

The equation (51) is a foundation of the energy dissipation. For removing any destructive energy component, (51) tells us the truth whatever the frequencies are produced by the harmonic and subharmonic waveforms and completely “damped” out by the ultra-high frequency modulation.

Observing (51), the function g(t) is an amplitude of power which is the amplitude-frequency dependent and seen the book [24, Chapter 3,4,5,6]. It means if the higher frequency ω produced, the more g(t) is attenuated. When moving the more higher frequency, the energy of (51) is the more rapidly diminished. We conclude that a large part of the power has been dissipated to the excited frequency ω fast drifting across the board of each reasonable resonant point, rather than transferred into the thermal energy (heat). After all, applying the energy to a system periodically causes the ω to be drifted continuously from low to very high frequencies for the energy absorbing and dissipating. Again removing the energy, the frequency rapidly returns to the nominal state. It is a fast recovery feature. That is, this system can be performed and quickly returned to the initial states periodically.

As the previous described, realized that the behavior of the frequency getting high as increasing the amplitude of energy and vice versa, expressed as the form of

ω=ω(g(t)) (52)

The amplitude-frequency relationship as (52) which induces the adaptation of system. It means which magnitude of the energy produces the corresponding frequency excitation like as a complex damper function (43).

onsider one typical example, assume that given the voltage

v(t)=V₀e^{j(ω}^{ᵥ}^{t+α}^{ᵥ}) (53)

and current

i(t)=I₀e^{j(ω}^{ᵢ}^{t+α}^{ᵢ}) (54)

the total applied power is defined as

$$\begin{matrix}P = {\int }_{0}^{T} i ( t ) v ( t ) d t & ( 55 ) \\ = \frac{{V}_{0} {I}_{0}}{( {ω}_{v} + {ω}_{i} )} ( {e}^{j ( {α}_{v} + {α}_{i} + \frac{π}{2} )} ( 1 - {e}^{j ( {ω}_{v} + {ω}_{i} ) T} ) ) & ( 56 )\end{matrix}$$

Let the frequency ω and phase angle β be as

ω=ωᵥ+ωᵢ

and

β=αᵢ+αᵥ

then equation (56) becomes into the complex form of

$$\begin{matrix}P = π ( ω , β , T ) + j Q ( ω , β , T ) & ( 57 ) \\ = \frac{{V}_{0} {I}_{0}}{ω} \text{(} {e}^{j ( β + \frac{π}{2} )} \text{(} 1 - {e}^{jω T} \text{)} \text{)} & ( 58 )\end{matrix}$$

where real power π(ω, β, T) is

$$π ( ω , β , T ) = \frac{2 {V}_{0} {I}_{0} sin ( ω T ) cos ( 2 π - 2 β - ω T )}{ω} \qquad ( 59 )$$

and virtual power Q(ω, β, T) is

$$Q ( ω , β , T ) = \frac{2 {V}_{0} {I}_{0} sin ( ω T ) sin ( 2 π - 2 β - ω T )}{ω} \qquad ( 60 )$$

respectively. Observing (46), taking limit operation to (57), (56) or (58),

$${lim}_{ω -> ∞} \frac{{V}_{0} {I}_{0}}{ω} \text{(} {e}^{j ( β + \frac{π}{2} )} \text{(} 1 - {e}^{jω T} \text{)} \text{)} = 0 \qquad ( 61 )$$

the electric power P is able to filter out completely no matter how they are real power (59) or virtual power (60) via performing frequency-shift or Doppler's shift operation, where ωᵥ, ωᵢ are frequencies of the voltage v(t) and current i(t), and αᵥ, αᵢ are correspondent phase angles and T is operating period respectively. Let the real power to be zero,

$$2 π - 2 β - ω T = \frac{π}{2}$$

which means that the frequency ω is shifted to

$${ω}_{Vir} = \frac{1}{T} ( \frac{3 π}{2} - 2 β )$$

The total power (57) is converted to the maximized virtual power

$$\begin{matrix}Max ( Q ( {ω}_{Vir} , β , T ) ) = \frac{2 {V}_{0} {I}_{0} sin ( {ω}_{Vir} T )}{{ω}_{Vir}} \\ = \frac{2 {V}_{0} {I}_{0} cos ( 2 β )}{( \frac{3 π}{2} - 2 β )}\end{matrix}$$

Similarly,

$$2 π - 2 β - ω T = 0 or {ω}_{Re} = \frac{2}{T} ( π - β )$$

the total power (57) is totally converted to the maximized real power

$$\begin{matrix}Max ( π ( {ω}_{Re} , β , T ) ) = \frac{2 {V}_{0} {I}_{0} sin ( {ω}_{Re} T )}{{ω}_{Re}} \\ = \frac{{V}_{0} {I}_{0} T sin ( 2 β )}{( β - π )}\end{matrix}$$

In fact, moving out the frequency element ω as the (61) is power conversion between real power (59) and virtual power (60).

Maximized Power Transfer Theorem

Consider the voltage source Vₛ to be

Vₛ=V₀

and its correspondent impedance Zₛ

Zₛ=Rₛ+iQₛ

The impedance of the system load Z_{L} is

Z_{L}=R_{L}+jQ_{L}

The maximized power transmission occurrence if R_{L} and Q_{L} are varied, not to be the constants,

R_{L}=Rₛ (62)

where the resistor Rₛ is called equivalent series resistance or ESR and

Q_{L}=−Qₛ (63)

Comparing (62) to (63), the impedances of voltage source and the system load should be conjugated, i.e.,

Z_{L}=Zₛ*

then the overall impedance becomes the sum of Zₛ+Z_{L}, or

$$\begin{matrix}Z = {Z}_{s} + {Z}_{L} \\ = {R}_{s} + {R}_{L} + j ( {Q}_{s} + {Q}_{L} )\end{matrix} \qquad ( 64 )$$

The power of impedance consumption is

$$\begin{matrix}P = {I}^{2} {R}_{L} \\ = {( \frac{[ ( {R}_{s} + {R}_{L} ) - j ( {Q}_{s} + {Q}_{L} ) ]}{{( {R}_{s} + {R}_{L} )}^{2} + {( {Q}_{s} + {Q}_{L} )}^{2}} )}^{2} {V}_{0}^{2} {R}_{L}\end{matrix}$$

Let the imaginary part of P be setting to zero,

(Qₛ+Q_{L})=0 (65)

i.e.,

Qₛ=−Q_{L}

or resonance mode. In fact, it is an impedance matched motion. The power of the total impedance consumption becomes just real part only,

$$P = \frac{{V}_{0}^{2} {R}_{L}}{{( {R}_{s} + {R}_{L} )}^{2}}$$

From the basic algebra,

$$\frac{{R}_{s} + {R}_{L}}{2} \geq \sqrt{{R}_{s} {R}_{L}}$$

where Rₛ and R_{L} have to be the positive values,

Rₛ, R_{L}≧0 (66)

or

(Rₛ−R_{L})²=0

In other words, the resistance Rₛ and R_{L} are the same magnitudes as

Rₛ=R_{L} (67)

The power of impedance consumption P becomes an averaged power Pₐᵥ

$$\begin{matrix}{P}_{av} = \frac{1}{2} \frac{{V}_{0}^{2}}{{R}_{L}} \\ = \frac{{V}_{0}^{2}}{( 2 {R}_{L} )}\end{matrix} \qquad ( 68 )$$

and the total impedance becomes twice of the resistance R_{L} or Rₛ.

Z=2RL (69)

Let (63) be a zero, i.e., impedance matched,

Qₛ=Q_{L}=0 (70)

from (67), the total impedance and consumed power P are (69), (68) respectively. In other word, comparing the (1) to (70), it is hard to implement that the imaginary part of impedance (64) keeps zero. But applying the (2) and (3) operations into the form of (6), the results have been verified on the Cauchy-Riemann theorem, also it is a possible way to create the zero value of imaginary part of total impedance (64) or (6). Another way is producing a conjugated part of (64) or (6) dynamically and adaptively or order-∞ resonance mode. Consider two typical reactance loads, capacitor, shown in FIG. 5 and inductor, shown in FIG. 6 respectively. Any capacitor C can be decomposed into one ideal capacitor C′, series parasitic resistor Rₛ and parallel parasitic resistor Rₚ. Similarly, the inductor L is able to be decomposed into one ideal inductor L′, series parastic resistor Rₛ and parallel parastic resistor Rₚ. For a constructive LC network, its total equivalent resistance (real part of impedance) Rₑ is the function of Rₛ and Rₚ contributed from the parasitic resistances of inductors and capacitors.

### REFERENCES

[1] Nicholas Minorsky . Nonlinear oscillations. Van Nostrand, New York., http://www.alibris.com, 1962.
[2] Alberto Abbondandolo. Morse Theory for Hamiltonian Systems. CRC Press., http://www.crcpress.com/, 2000.
[3] D. K. Anand. An Introduction to Control Systems. Pergamon Press., http://www.amazon.com/, 1974.
[4] Tom M. Apostol. Mathematical Analysis. Addison-Wesley Publishing Company., http://www.aw-bc.com/, 2nd edition, 1975.
[5] V. I. Arnold. Ordinary Differential Equations. MIT Press., http://www.mitpress.com/, 1973.
[6] V. I. Arnold. Geometrical Methods in the Theory of Ordinary Differential Equations. Springer-Verlag., http://www.springer-ny.com/, 2nd edition, 1988.
[7] V. I. Arnold. Theory of Singularities and its Applications., volume 1. American Mathematicial Society., http://www.ams.org/, 2nd edition, 1990.
[8] Donald R. Askeland. The Science and Engineering of Materials. PWS Publishers., alternate edition, 1985.
[9] J. Balakrishnan. A geometric framework for phase synchronization in coupled noisy nonlinear systems. Physical Review E, 73:036206, 2006.
[10] Timoteo Carletti and Gabriele Villari. A note on existence and uniqueness of limit cycles for li 'enard systems, 2003.
[11] V. K. Chandrasekar, M. Senthilvelan, and M. Lakshmanan. An unusual li 'enard type nonlinear oscillator with properties of a linear harmonic oscillator, 2004.
[12] E. T. Copson. An introduction to the theory of functions of a complex variable. Oxford University Press., http://www.amazon.com/, 4th edition, 1948.
[13] M. C. Cross, A. Zumdieck, Ron Lifshitz, and J. L. Rogers. Synchronization by nonlinear frequency pulling. Physical Review Letters, 93:224101, 2004.
[14] R. Wong F. Cuker. The Collected Papers of Stephen Smale., volume 3. Singapore University Press., http: //www.worldscibooks.com/mathematics, 2000.
[15] H. Giacomini and S. Neukirch. On the number of limit cycles of the lienard equation, 1997.
[16] Jaume Gine and Maite Grau. A note on “relaxation oscillators with exact limit cycles”, 2005.
[17] John Guckenheimer and Philip Holmes. Nonlinear Oscillations, Dynamical Systems, and Bifurcations of Vector Fields. Springer-Verlag., http://www.springer-ny.com/, 1997.
[18] Ernest A. Guillemin, editor. Synthesis of Passive Networks: Theory and Methods Appropriate to the Realization and Approximation Problems. John Wiley and Sons., 1957.
[19] Edward H. Hellen and Matthew J. Lanctot. Nonlinear damping of the Ic circuit using anti-parallel diodes, 2006.
[20] Arthur R. Von Hippel. Dielectrics and Waves. A John Wiley and Sun, Inc., http://www.wiley.com, 1954.
[21] Arthur Von Hippel. Dielectric Materials and Applications. Artech House Publishers., http://www.artechhouse.com, 1995.
[22] Morris W. Hirsh and Stephen Smale. Diffcrcntial Equations, Dynamical Systems and Linear Algebra. Academic Press., http://www.academicpress.com/, 1974.
[23] Thomas J. R. Hughes. Jerrold E. Marsden. Mathematical Foundations of Elasticity. Prentice-Hall, Inc., http://www.doverpublications. com/, 1984.
[24] D. W. Jordan and Peter Smith. Nonlinear Ordinary Diffcrcntial Equations. Oxford University Press., http://www.oup.co.uk/academic/, 3rd edition, 1999.
[25] Yitzhak Katznelson. An Introduction to Harmonic Analysis. Cambridge University Press, http://www.amazon.com/, 2nd edition, 1968.
[26] Alexandra S. Landsman and Ira B. Schwartz. Predictions of ultra-harmonic oscillations in coupled arrays of limit cycle oscillators, 2006.
[27] Serge Lang. Complex Analysis. Springer-Verlag., http://www.springer.de/phy/books/ssp, 4th edition, 1999.
[28] Jose-Luis Lopez and Ricardo Lopez-Ruiz. The limit cycles of lienard equations in the strongly non-linear regime, 2002.
[28] Jose-Luis Lopez and Ricardo Lopez-Ruiz. Approximating the amplitude and form of limit cycles in the weakly non-linear regime of lienard systems, 2006.
[29] Jose-Luis Lopez and Ricardo Lopez-Ruiz. The limit cycles of lienard equations in the weakly nonlinear regime, 2006.
[30] A. J. Moulson and J. M. Herbert. Electrocramics: Materials, Properies, Applications. Wiley and Sun Ltd., http://www3.wileye.com, 2nd edition, 2003.
[32] Peter J. Olver. Applications of Lie Groups to Differential Equations. Springer-Verlag., http: //www.springer-ny.com/, 1993.
[33] Lawrence Perko. Diffcrcntial Equations and Dynamical Systems. Springer-Verlag, New York, Inc., http://www.springer-ny.com, 3rd edition, 2000.
[34] Jerrold E. Marsden. Ralph Abraham. Foundations of Mechanics. Perseus Publishing., http: //www.perseusbooksgroup.com/front.html, 2nd edition, 1984.
[35] Michael Reed and Barry Simon. Methods of Modern Mathematical Physics: Foutrir Analysis, Self-Adjointness., volume 2. Academic Press., http://www.academicpress.com, 1975.
[36] Michael Reed and Barry Simon. Methods of Modern Mathematical Physics: Analysis of Operators., volume 4. Academic Press., http: //www.academicpress.com, 1978.
[37] Michael Reed and Barry Simon. Methods of Modern Mathematical Physics: Scattering Theory., volume 3. Academic Press., http://www.academicpress.com, 1979.
[38] George F. Simmons. Introduction to Topology and Modern Analysis. McGRAW-HILL Inc., http://books.mcgrawhill.com, 1963.
[39] Ali Taghavi. On periodic solutions of lienard equations, 2004.
[40] E. T. Whittaker and G. N. Watson. A Course of Modern Analysis. Cambridge Mathematical Library., http://www.cambridge.org, 4th edition, 1927.
[41] Matthew Sands. WRichard P. Feynman, Robert B. Leighton. Feynman Leceturs On Physics: The Complete And Definitive Issue., volume 3. Addison Wesley Publishing Company., http://www.aw-bc.com, 2nd edition, 1964.
[42] A. David Wunsch. Complex Variables with Applications. Addison-Wesley Publishing Company Inc., http://www.awbc.com/, 1983.

### SUMMARY OF THE INVENTION

It is a first objective of the present invention to provide a new structure of a field-interacted p-n junction device which can interact and couple with the fields.

It is a second objective of the present invention to provide the field-interacted p-n junction device with self-excited output.

It is a third objective of the present invention to employ the field-interacted p-n junction device into the application of solar-cell, light sensor, Hall device, switch, LED, switch or capacitor.

### BRIEF DESCRIPTION OF THE DRAWINGS

FIG. 1 has shown a parallel oscillator;

FIG. 2 has shown a serial Oscillator;

FIG. 3 has shown the function F(x) and a trajectory Γ of Liènard system;

FIG. 4 has shown the impedance function F(x) is independent of the initial condition setting;

FIG. 5 a capacitor C decomposed into an ideal capacitor C′, a series parasitic resistor Rₛ and a parallel parasitic resistor Rₚ;

FIG. 6 an inductor L decomposed into an ideal capacitor C′, a series parasitic resistor Rₛ and a parallel parasitic resistor Rₚ;

FIG. 7a has shown a characteristic curve of a typical tunnel diode;

FIG. 7b has shown the structure of a typical tunnel diode in which a heavily doped p-n junction is formed between a p-type and a n-type semiconductors;

FIG. 7c has shown the structure of a field tunnel diode by introducing the PDR and NDR concepts into the tunnel diode of FIG. 7b;

FIG. 7d has shown an embodiment of a multi-band waveforms;

FIG. 7e has shown an embodiment of a single-band waveform;

FIG. 8a has shown that the field tunnel diode of FIG. 7c is a solarcell device;

FIG. 8b has shown that the field tunnel diode of FIG. 7c is a light sensor or Hall device;

FIG. 8c has shown that the field tunnel diode of FIG. 7c is a light sensor;

FIG. 9a has shown the structure of a field tunnel transistor;

FIG. 9b has shown that the field tunnel transistor of FIG. 9a is a solarcell device;

FIG. 9c has shown that the field tunnel transistor of FIG. 9a is a light sensor or Hall device;

FIG. 9d has shown that the field tunnel transistor of FIG. 9a is a light sensor;

FIG. 10 has shown that the field tunnel transistor can be employed as an active switch;

FIG. 11a has shown the structure of a typical LED;

FIG. 11b has shown the structure of an inventive LED;

FIG. 11c has shown an embodiment by employing the LED of FIG. 11b to control the illumination of the LED;

FIG. 12a has shown the structure of a field capacitor whose capacitance can be actively controlled; and

FIG. 12b has shown a circuit by employing the field capacitor of FIG. 12a.

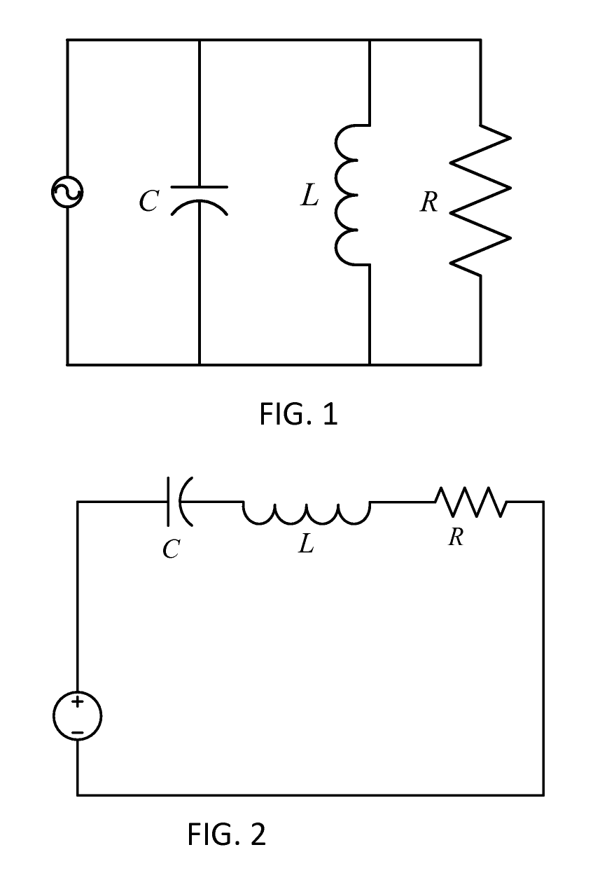

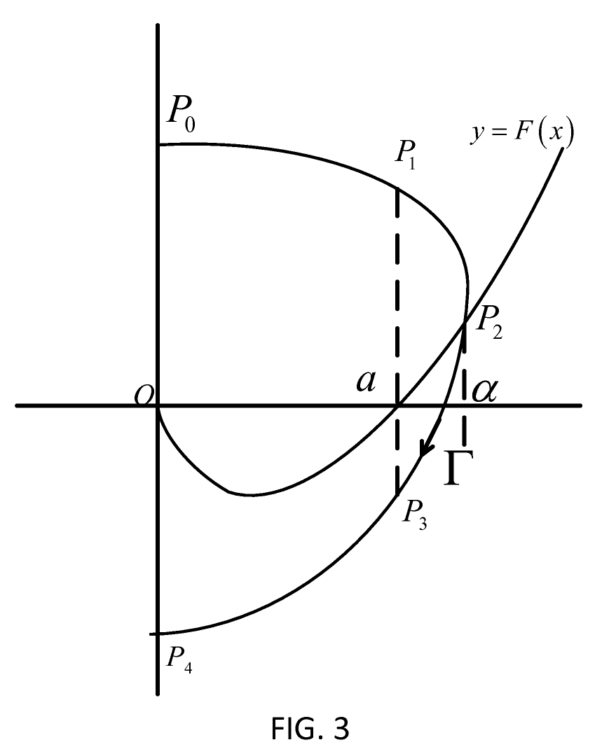

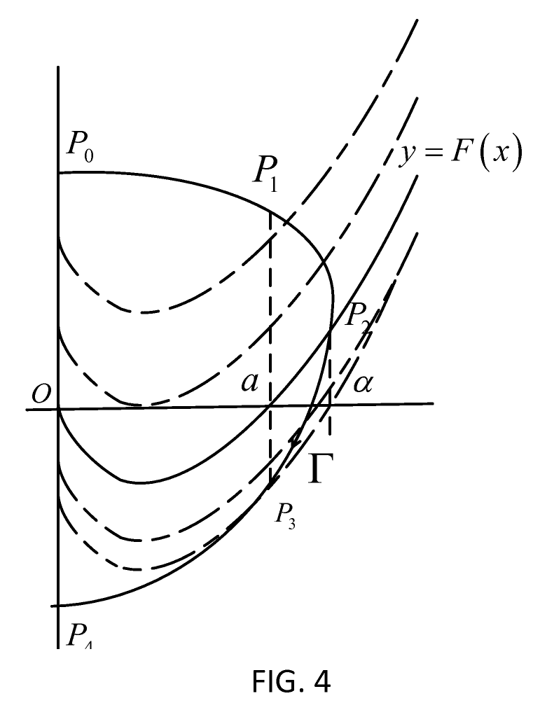

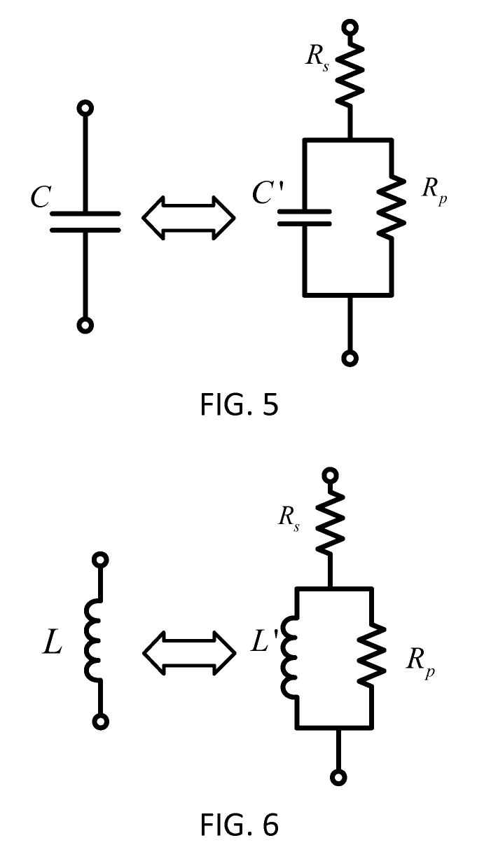

### DETAILED DESCRIPTION OF THE INVENTION

According to the equations (12) above, the resistance variations can be generated by fields interaction. And, according to the equations (14) and (15), the positive differential resistor or PDR in short defined by (18) or (28) and the negative differential resistor or NDR in short defined by (19) or (30) can be generated by fields interaction in which the field can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them listed above. The PDR and NDR in the present invention are not limited to be produced by any particular field. A device having PDR or NDR property can be respectively called PDR or NDR in the present invention. A PDR can also be expressed as a device having PDR property in the present invention and a NDR can also be expressed as a device having NDR property in the present invention.

According to the equations (14) and (15), the reactance variations can be described by the resistance variations in an electrical system, in other words, unlimited resistance variations can be equivalent to an infinite number of L-C networks. Making resistance variations is much easier than by making reactance variations and one of making resistance variations can be realized by a PDR and a NDR serially coupled with each other. According to the discussion in the background information section a serially coupled PDR and NDR can be a damper. A serially coupled PDR and NDR can generate self-induced frequency elements which can modulate together to generate very broad frequency responses. Any device having PDR and NDR properties will have broader frequency responses than that of the device without PDR and NDR properties.

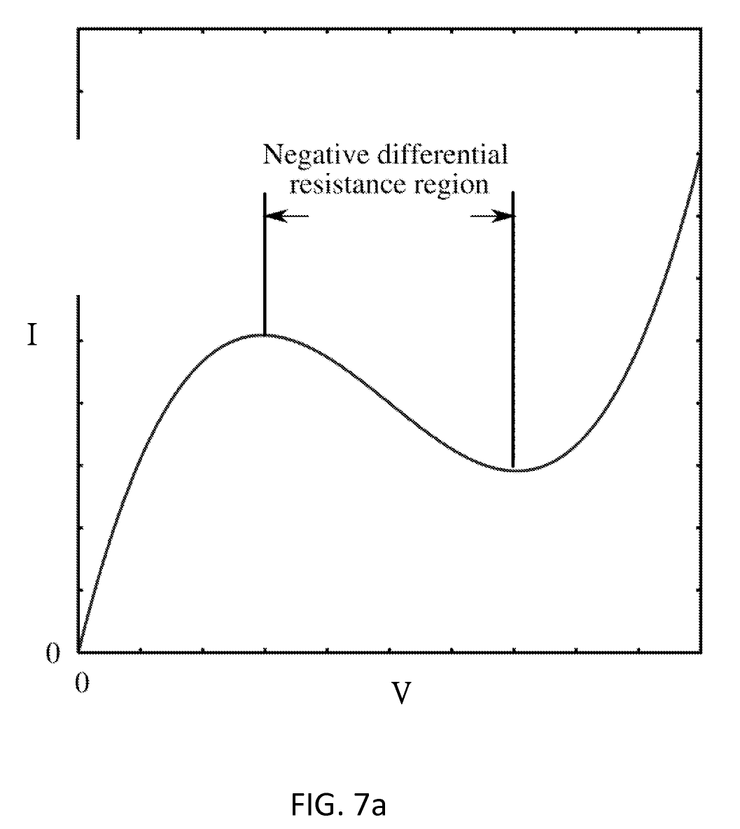

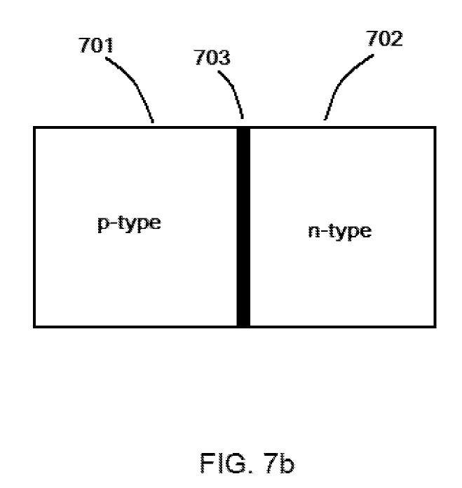

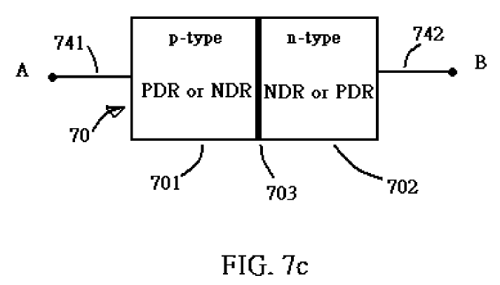

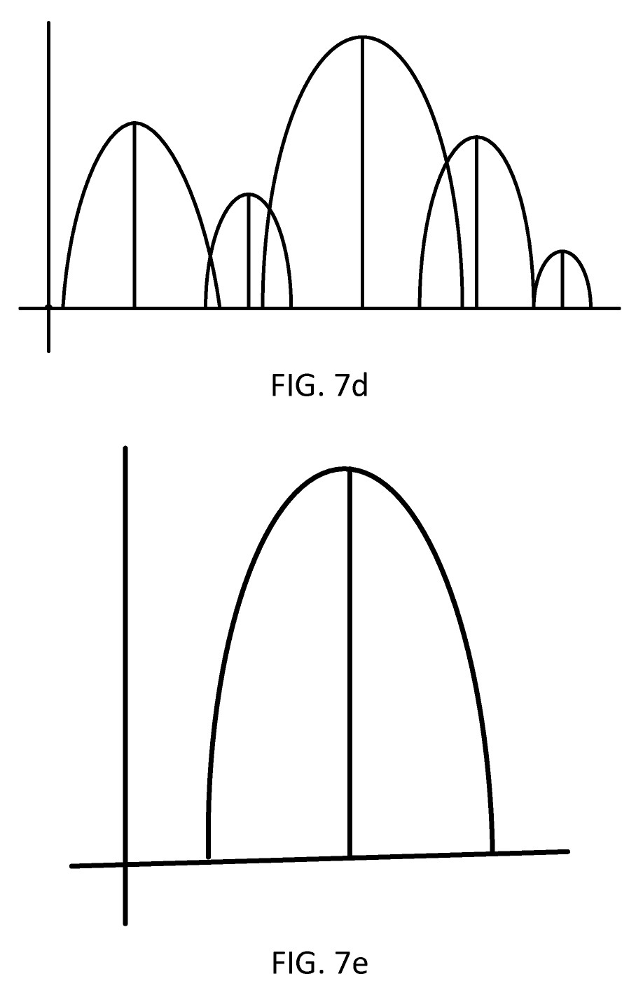

FIG. 7b has shown the structure of a typical tunnel diode in which a heavily doped p-n junction 703 is formed by coupling a p-type 701 with a n-type 702. The p-n junction formed by the p-type and n-type of a tunnel diode can be called as tunneling junction in the present invention. A tunnel diode can be expressed as a diode having tunneling effect in the present invention. The present invention is not limited to any particular structure and design constructing a tunneling junction of tunnel diode, in other words, the present invention includes all the possible structures and designs constructing tunneling junction of tunnel diode.

A field tunnel diode shown in FIG. 7c is obtained by defining either one of the p-type 701 or n-type 702 shown in the tunnel diode of FIG. 7b as a PDR and the other one as a NDR. As earlier revelation the PDR and NDR can be generated by fields interaction in which the field can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them. The field tunnel diode of FIG. 7c might need terminals for coupling outside circuit. A first and second terminals 741 and 742 respectively couple the p-type 701 and the n-type 702 as shown in FIG. 7c. The field tunnel diode will be benefited if the first and second terminals are NDRS, for example, the benefit includes the improved sensitivity of the field tunnel diode. The fields mentioned above applied to the field tunnel diode can be thru contacting or non-contacting way depending on the types of the field.

A field applied to the field tunnel diode generates the variation of the diode's resistance (PDR and NDR) which can change the voltage level for the tunneling happening resulting in increasing the chances for generating tunneling, and the produced PDR, NDR and tunneling junction will couple and modulate together to generate more frequency elements so that the field tunnel diode will present self-excited multi-band waveforms while a typical tunnel diode presents only single-band waveform, which means that a field applied to the field tunnel diode can be frequency-modulated (FM) by and coupled into the field tunnel diode so that the field tunnel diode can also be viewed as a field-interacted device. The coupling PDR and NDR of the field tunnel diode can generate self-induced frequency elements which can modulate together to generate very broad frequency responses, which makes the field tunnel diode a broadband tunnel diode.

The concepts of multi-band waveforms and single-band waveform are respectively demonstrated in the spectrums of FIGS. 7d and 7e. The area covered by the waveform represents the signal's amplitude or energy level, obviously, the area covered by the multi-band waveforms is bigger than that covered by single band, which means that the signal can be more significantly decomposed into the multi-band waveforms.

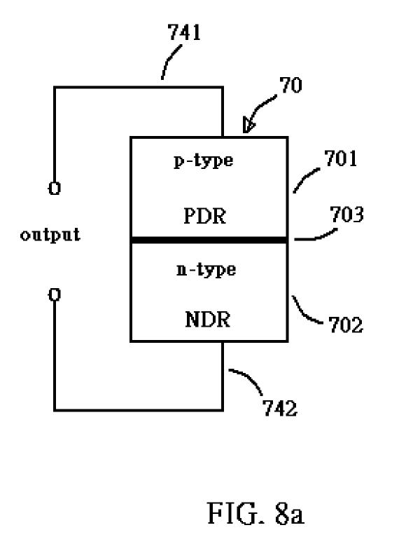

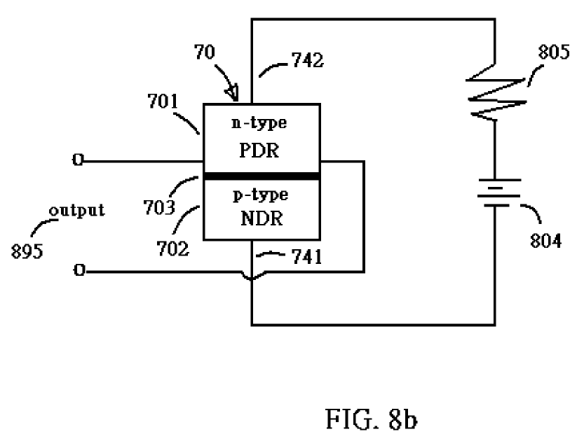

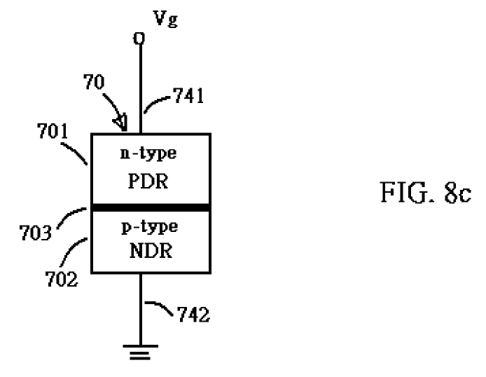

The field tunnel diode can be a solarcell device shown in FIG. 8a which frequency-modulates (FM) and couples an incident light and outputs self-excited multi-band waveforms while a typical solarcell only outputs DC level.

The field tunnel diode can be a light sensor such as charged-coupled device (CCD) or a Hall device which has been shown in FIG. 8b. The CCD or Hall device 70 is powered by a power source 804 and its two transversal sides are used as output. For the application of CCD, the PDR and NDR are generated by optical field and then generate self-excited multi-band waveforms output 895. For the Hall device, the PDR and NDR are generated by magnetic field and then generate self-excited multi-band waveforms output 895. FIG. 8c has shown another circuit of CCD by employing the field tunnel diode of FIG. 7c. It's noted that the PDR and NDR of the field tunnel diode can also be interacted by thermal, acoustic or pressure field, or any combinations of them as revealed above so that the field tunnel diode can be a thermal device which converts thermal field into electricity, or/and an acoustic device which converts acoustic field into electricity or/and pressure device which converts pressure field into electricity.

The characteristic of field tunnel diode and tunnel diode have shown that the resistance can be varied between very large number, which can be viewed as “off” state, and zero, which can be viewed as “on” state, so that they can be viewed as a self-excited switch. Field tunnel diode is a passive device which can not be actively controlled. A field tunnel transistor has been invented for being an active device such as a controllable switch, and it has amplification function and broader bandwidth than that of the field tunnel diode.

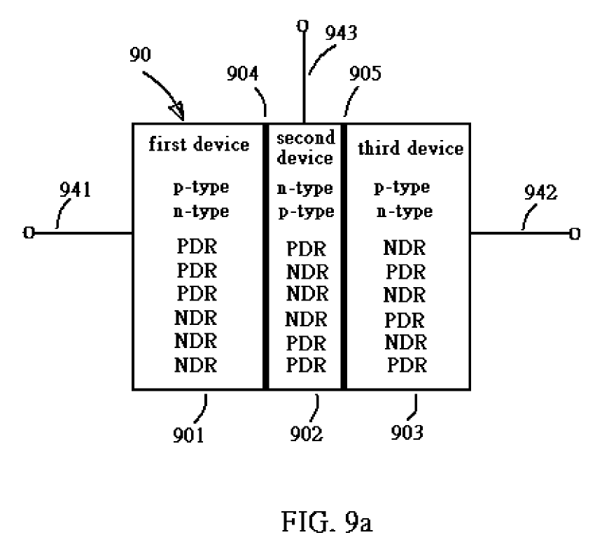

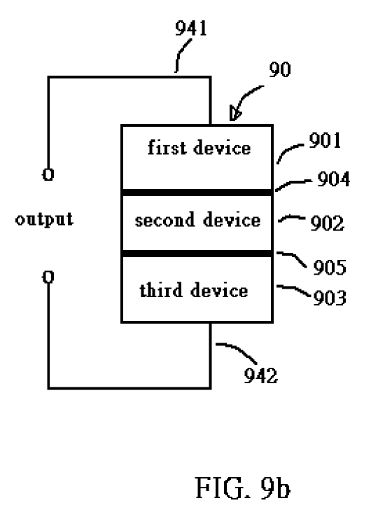

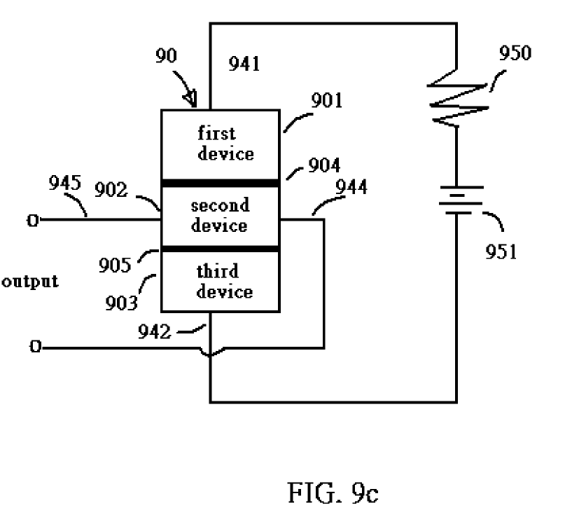

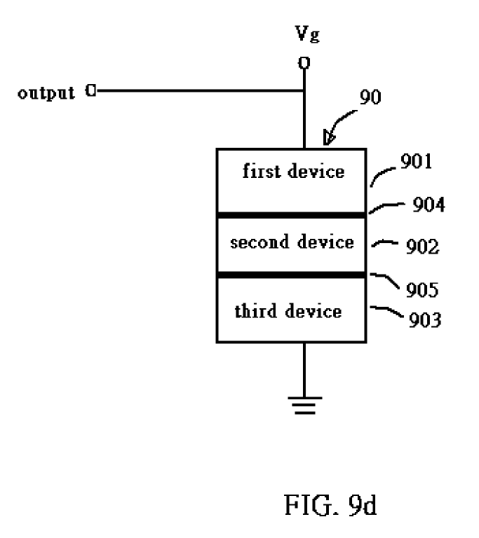

FIG. 9a has shown a field tunnel transistor 90 in the structure of p-n-p or n-p-n type as a typical transistor. FIG. 9a has shown that a first device 901 couples with a second device 902 which couples with a third device 903, in which the first 901 and second 902 devices construct a first tunnel diode and the second 902 and third 903 devices construct a second tunnel diode. FIG. 9a has shown that a first tunneling junction 904 is formed between the first 901 and second 902 devices and a second tunneling junction 905 is formed between the second 902 and the third 903 devices. The first 901, second 902 and third 903 devices are either respectively as an type arrangement of p-n-p or n-p-n.

The field tunnel transistor 90 of FIG. 9a might need terminals for coupling outside circuit. A first 941, second 942 and third 943 terminals respectively couple the first 901, second 902 and third 903 devices as shown in FIG. 9a. The field tunnel transistor will be benefited if the first, second and third terminals are NDRS, for example, the benefit includes the improved sensitivity of the field tunnel transistor. The fields interacting with the field tunnel transistor can be thru contacting or non-contacting way depending on the types of the field.

Among the first 901, second 902 and third 903 devices includes at least a PDR and a NDR coupled in series. For example, the arrangement of the first 901, second 902 and third 903 can be an arrangement of PDR-PDR-NDR, PDR-NDR-PDR, PDR-NDR-NDR, NDR-PDR-NDR, NDR-NDR-PDR or NDR-PDR-PDR in which the PDR-NDR-PDR and NDR-PDR-NDR are the better choices for both the two tunneling junctions 904, 905 are formed with a PDR and a NDR. All the possible arrangements are listed in the embodiment of FIG. 9a.

The first 904 and second 905 tunneling junctions can be any structure of the first and second tunnel diodes respectively formed by the first 901 and second 902 devices and the second 902 and third 903 devices, in other words, the present invention is not limited to any particular structure of the tunneling junction constructing the tunnel diode. As earlier revelation the PDR and NDR can be generated by fields interaction in which the field can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them. The fields mentioned above applied to the field tunnel transistor can be thru contacting or non-contacting way depending on the types of the field.

The frequency responses of the two tunneling junctions 904, 905 are very possibly different and the two tunneling junctions with the fields interacteded PDR and NDR will couple and modulate together to violently generate more frequency elements than that of the field tunnel diode so that the bandwidth and waveforms of the field tunnel transistor 90 are even broader and more complicated than that of a field tunnel diode 70.

The field tunnel transistor 90 shown in FIG. 9a can be a solarcell device which frequency-modulates (FM) and couples an incident light and outputs self-excited multi-band waveforms which even broader and more complicated than the solarcell made of the field tunnel diode. FIG. 9b has shown the solarcell 90 in which the PDR and NDR will be initially generated by incident light and then the two tunneling junctions 904, 905 with the fields generated PDR and NDR will generate self-excited multi-band waveforms output taken between the first 901 and third 903 devices (or the first 941 and third 943 terminals).

The field tunnel transistor shown in FIG. 9a can be a light sensor such as charged-coupled device (CCD) or a Hall device which has been shown in FIG. 9c. The light sensor or Hall device 90 is powered by a power source 951 and its two transversal sides, which are respectively coupled by terminals 944 and 945, are used as output. For the application of light sensor, the PDR and NDR are generated by optical field and for the Hall device the PDR and NDR are generated by magnetic field. FIG. 9d has shown another circuit of light sensor employing the field tunnel transistor 90 of FIG. 9a. A power Vg is for overcoming the two tunneling junctions's bandgaps to conduct the field tunnel transistor and the light generated PDR and NDR with the two tunneling junctions will couple and modulate together to output self-excited multi-band waveforms.

The PDR and NDR of the field tunnel transistor 90 of FIG. 9a can be interacted by thermal field, which means that the field tunnel transistor is a thermal device which converts thermal field into electricity. The same logic applies, the the field tunnel transistor can be an acoustic device which converts acoustic field into electricity or the field tunnel transistor can be a pressure device which converts pressure field into electricity.

Another embodiment, the PDR and NDR of the field tunnel transistor can be interacted by a plurality of fields at the same time, which means that the plurality of the fields can be coupled into the field tunnel transistor at the same time. As stated earlier, the PDR and NDR of the field tunnel transistor can be generated by fields interaction in which the field can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them. One of the embodiment, the field can be applied on the field tunnel transistor transversely to the current direction.

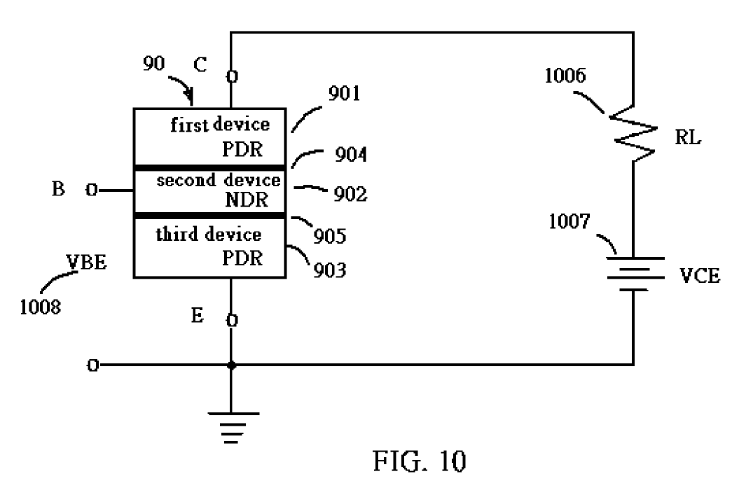

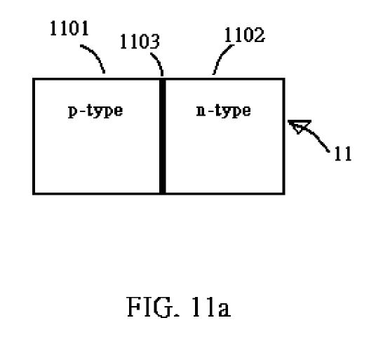

The field tunnel transistor can be used as an active switch which has been shown in FIG. 10. A supply voltage VCE 1007 is applied across the emitter and collector terminals, with the (+) positive terminal of the voltage source connected through a load resistor RL1006 to the collector terminal. Applying a positive voltage between the base and emitter terminals VBE 1008 turns the transistor on. Decreasing the VBE 1008 turns the transistor off. The fields generated PDR and NDR with the two tunneling junctions 904, 905 will couple and modulate together to generate self-excited multi-band waveforms which will be carried on a baseband input on the VBE.

To control precisional “on” and “off” switchings is the goal pursued by any switch, which is more difficult and important in the high power and high frequency applications. The switch used in the high power condition requires bigger junction area which sets a speed and precisional limits, for example, once a switch is on and it can't be off on time, which can harm the circuit.

One of the main reason to the problem arises from that the frequency of the baseband is not as high as the frequency responses of the p-n junction, in other words, the baseband is not at the same or near level of the frequency response of the p-n junction so that the p-n junction has very big chances to miss the “off” from baseband. The frequency responses of the self-excited carriers carried on the baseband can have very big chances to match the frequency response of the p-n junction so that the precise “on” and “off” can be obtained. The existence of the very broad and complicated carrier carried on the baseband will relief the speed limit on the baseband in a certain degree so that a higher frequency and more reliable switch can be realized. Furthermore, the self-excited carriers carried on the baseband have very big chances to match the frequency response of parasitic capacitances in the p-n junction, which has been known as Miller effect, and cancel the Miller effect to minimize the noises.

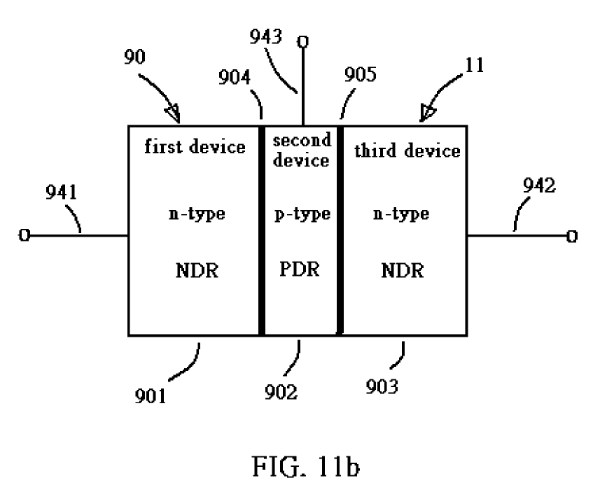

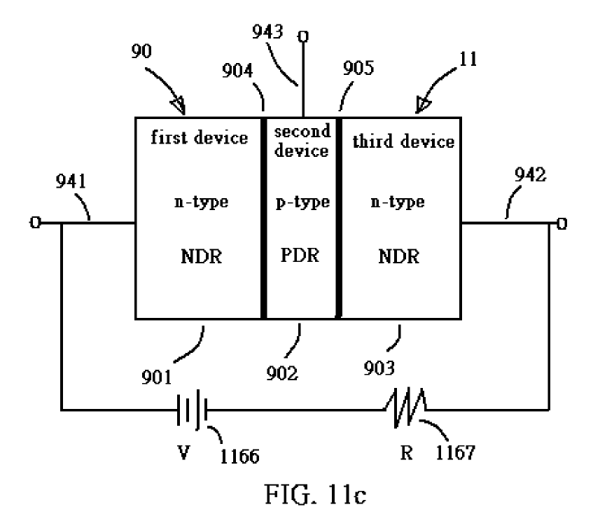

A light-emitting diode (LED) is a semiconductor diode that emits light when an electric current is applied in the forward direction of the device. The effect is a form of electroluminescence where incoherent and narrow-spectrum light is emitted from the p-n junction. Like a normal diode, the LED consists of a chip of semiconducting material impregnated, or doped, with impurities to create a p-n junction. The structure of a typical LED can be simply expressed in FIG. 11a in which a p-type 1101 couples with a n-type 1102 and a p-n junction 1103 formed between them includes all the possible optics materials and structures. The p-n junction 1103 of the LED 11 of FIG. 11a responsible for emitting light can also be called LED p-n junction in the present invention.

A new light-emitting device can be obtained by slightly modifying the field tunnel transistor 90 of FIG. 9a. The light-emitting device can be obtained by replacing either one of the first or second tunnel diode of the field tunnel transistor 90 of FIG. 9a with a LED.

An embodiment of the light-emitting device 11 has been shown in FIG. 11b, the second tunnel diode constructed by the second 902 and third 903 devices is chosen as the LED and the first 901, second 902 and third 903 devices are the arrangements of n-p-n type and NDR-PDR-NDR. As stated before, the first tunneling junction 904 with the fields produced NDR and PDR will couple and modulate together to violently generate very broad self-excited multi-band waveforms which can very possibly fall into the light-emitting frequency bandwidth for the LED p-n junction to emit light. If the frequency response of the generated multi-band waveforms are not high enough up to the level of the light-emitting frequency of the LED p-n junction at least a frequency element outside the LED device such as a PWM is needed to be modulated into the light-emitting device, in which the added frequency element will multiply the frequency response of the tunneling junction to reach the light-emitting frequency of the LED. The LED p-n junction and tunneling junction should be disposed as close as possible making sure the frequency responses of the tunneling junction carried onto the LED p-n junction.

For example, the frequency response of tunneling junction is usually at the level of x-band (about 10¹⁰) which is a lot lower than the level at 10¹⁴ of light-emitting frequency of the LED p-n junction. One way to solve the problem is to modulate in another frequency elements which will multiply the frequency response of tunneling junction reaching the frequency level for the LED p-n junction to emitting light.

The NDR or/and PDR of the light-emitting device shown in FIG. 11b can be changed by fields interaction applied to it resulting in changing the LED p-n junction's resistance, which means that the illumination of the LED p-n junction can be controlled by fields interaction in which the field can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them listed above. The fields mentioned above applied to the light-emitting device can be thru contacting or non-contacting way depending on the types of the field. For example, an embodiment of a circuit shown in FIG. 11c is obtained by employing the light-emitting device of FIG. 11b and FIG. 11c has shown that the light-emitting device is powered by a power source 1166. When another electrical field is applied to the second device 902 thru the third terminal 943 then the LED p-n junction's resistance is changed resulting in the changing of the illumination of the LED p-n junction. This is an example of the illumination of the light-emitting device controlled by electrical field.

One of the important advantage of the inventive light-emitting device is that it can use any existed and mature LED technology. And, the very broad and coherence induced spectrum spreadings make the inventive light-emitting device output richer and softer optical spectrum than that of a traditional LED device and its output is in the form of power not in the resistant type any more.

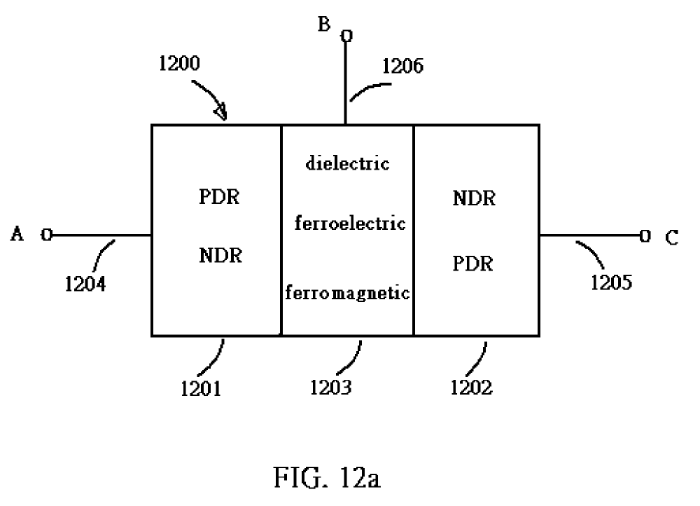

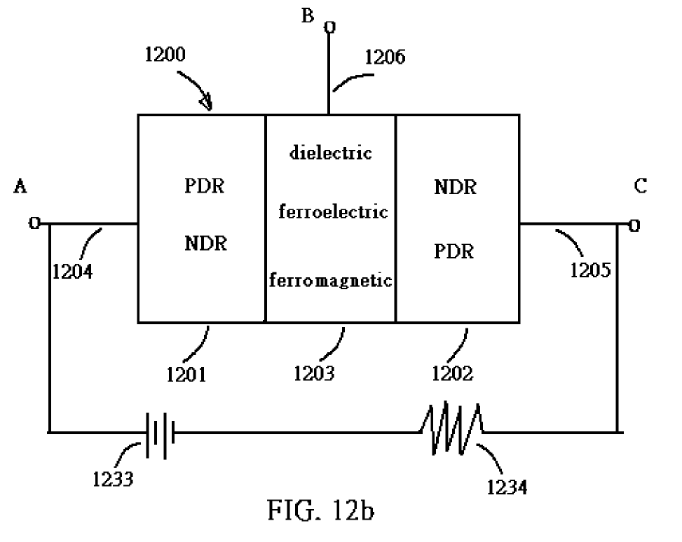

A field capacitor 1200 with controllable capacitance has been shown in FIG. 12a. The capacitor 1200 comprises a first conductive electrode 1201, a second conductive electrode 1202, and a dielectric 1203 in which the dielectric 1203 is disposed between the two conductive electrodes 1201, 1202 and the dielectric 1203 in physical contacts with the two conductive electrodes 1201 and 1202 as a typical capacitor. Either the first or second electrode is PDR and the other electrode is NDR.

The capacitor 1200 might need terminals for coupling outside circuits in which a first 1204 and a second 1205 terminals respectively couple the first 1201 and second 1202 electrodes and a third terminal 1206 couples the dielectric 1003.

The selection of a dielectric is one of the key element contributed to the capacitance of the capacitor. Some dielectrics such as ferroelectric and ferromagnetic materials will polarize if they are respectively under the application of electrical and magnetic fields.

The changing of the polarization generates the changing of the capacitance of the capacitor 1200. And, the PDR and NDR can be interacted by fields applied it, which also get involved in the changing of the capacitance of capacitor 1200. Furthermore, the serially coupling of the PDR and NDR functions as damper which will generate more frequency elements to make the capacitor 1200 a very broadband capacitor. And, the changing of the polarization generates the changing of frequency responses that produces the damping effect resulting in the frequency shifting.

A circuit shown in FIG. 12b employing the capacitor of FIG. 12a has shown that the capacitor 1200 is powered by a power source 1233 and, obviously, the capacitor 1200 is under an electrical condition from the power source 1233. When an another electrical field is applied to the dielectric 1203 of the capacitor 1200 thru the third terminal 1206 the polarization built by the power source 1233 is changed, which results in the changing of the capacitance of the capacitor 1200.

The present invention has proved that the capacitance of the capacitor can be actively controlled by external fields which can be temperature field T, magnetic field such as magnetic flux intensity B, optical field such as optical field intensity I, electric field such as voltage v, current i, frequency f or electrical power P, acoustic field, or mechanical field such as magnitude of force F, and so on, or, any combinations of them listed above. The PDR and NDR are fields-interacted devices and the coupling of the PDR and NDR has dampering effect which can effectively broaden the frequency response of the capacitor 1200 and make the capacitor 1200 a broadband capacitor.

The field applied to the capacitor 1200 can be thru contacting or non-contacting way depending on the types of the field. For example, an electrical field is applied thru the third terminal 1206 to the capacitor 1200 in the embodiment of FIG. 12b, which is a contacting way. A magnetic field can be applied to the capacitor 1200 under non-contacting condition.

The present invention is not limited to any particular dielectric, for example, the dielectric can be constructed by ferroelectric or ferromagnetic material. The dielectric can be interacted by fields so that it can also be called field-interacted dielectric in the present invention.

1. A tunnel diode, comprising,
a p-type device which is PDR or NDR, and
a n-type device which is NDR or PDR coupled with the p-type device,
wherein
either the p-type device or the n-type device is a PDR and the other device is a NDR, and the PDR and NDR are generated by thermal field, optical field, electric field, pressure field, or acoustic field, or any combinations of them.

2. The tunnel diode of claim 1, further comprising a first terminal coupled with the p-type device, a second terminal coupled with the n-type device, a third and fourth terminals respectively coupled with two transversal sides of the diode for coupling outside circuit, wherein the first, second, third and fourth terminals are NDRS.

3. The tunnel diode of claim 1, wherein the tunnel diode is solarcell device which converts incident light into electrical power.

4. The tunnel diode of claim 1, wherein the tunnel diode is light sensor which converts incident light into electrical signal.

5. The tunnel diode of claim 1, wherein the tunnel diode is Hall device which converts magnetic field into electricity.

6. The tunnel diode of claim 1, wherein the tunnel diode is thermal device which converts thermal field into electricity.

7. The tunnel diode of claim 1, wherein the tunnel diode is pressure device which converts pressure field into electricity.

8. The tunnel diode of claim 1, wherein the tunnel diode is acoustic device which converts acoustic field into electricity.

9. A transistor comprising:
a first device which is p-type or n-type and is PDR or NDR,
a second device which is p-type or n-type and is PDR or NDR coupled with the first device to form a first tunnel diode, and
a third device which is p-type or n-type and is PDR or NDR coupled with the second device to form a second tunnel diode, wherein
the first, second and third devices comprises a PDR and a NDR, and
the PDR and NDR are generated by thermal field, optical field, electric field, pressure field, or acoustic field, or any combinations of them.

10. The transistor of claim of 9, further comprising a first terminal coupled with the first device, a second terminal coupled with the third terminal, a third terminal coupled with the second device, and a fourth and a fifth terminals respectively coupled with two transversal sides of the transistor for coupling outside circuits, wherein the first, second, third, fourth and fifth terminals are NDRS.

11. The transistor of claim 9, wherein the transistor is solarcell device which converts incident light into electrical power.

12. The transistor of claim 9, wherein the transistor is light sensor which converts incident light into electrical signal.

13. The transistor of claim 9, wherein the transistor is Hall device which converts magnetic field into electricity.

14. The transistor of claim 9, wherein the transistor is thermal device which converts thermal field into electricity.

15. The transistor of claim 9, wherein the transistor is pressure device which converts pressure field into electricity.

16. The transistor of claim 9, wherein the transistor is acoustic device which converts acoustic field into electricity.

17. The transistor of claim 9, wherein the transistor is switch.

18. The transistor of claim 9, wherein the transistor is light-emitting device by replacing the first tunnel diode or the second tunnel diode with a light-emitting diode (LED).

19. A capacitor, comprising:
a first electrode having PDR property;
a second electrode having NDR property; and
a field-interacted dielectric disposed between the first and second electrodes and coupled with the first and second electrodes, wherein the field-interacted dielectric is interacted by thermal field, optical field, electric field, pressure field, or acoustic field, or any combinations of them for controlling the capacitance of the capacitor, and the PDR and NDR are generated by thermal field, optical field, electric field, pressure field, or acoustic field, or any combinations of them.

20. The capacitor of claim 19, wherein the field-interacted dielectric is made of ferroelectric or ferromagnetic material.
